(19) United States
(12) Patent Application Publication
(10) Pub. No.: US 2022/0106703 A1
(43) Pub. Date: Apr. 7, 2022

(54) SEMICONDUCTOR CRYSTAL GROWTH DEVICE

(71) Applicant: ZING SEMICONDUCTOR CORPORATION, Shanghai (CN)

(72) Inventors: Weimin SHEN, Shanghai (CN); Gang WANG, Shanghai (CN); Xianliang DENG, Shanghai (CN)

(21) Appl. No.: 17/427,765

(22) PCT Filed: Jan. 16, 2020
(86) PCT No.: PCT/CN2020/072522

§ 371 Date: Aug. 2, 2021

(30) Foreign Application Priority Data
Feb. 1, 2019 (CN) 201910104706.5

(51) Int. Cl. C30B 15/14; C30B 15/00; C30B 29/06

(52) U.S. Cl. CPC C30B 15/14; C30B 29/06; C30B 15/007

(57) ABSTRACT

The present invention provides a semiconductor crystal growth device, comprising: a furnace body; a crucible disposed inside the furnace body for containing a silicon melt; a pulling unit disposed at a top portion of the furnace body for pulling out a silicon ingot from the silicon melt; and a heat shield unit including a flow tube that is barrel-shaped and disposed around the silicon ingot for rectifying argon gas input from the top portion of the furnace body and adjusting thermal field distribution between the silicon ingot and the silicon melt liquid surface, wherein, the heat shield unit further includes an adjustment unit disposed at a lower end inside the flow tube for adjusting a minimum distance between the heat shield unit and the silicon ingot. According to the present invention, by providing the adjustment unit at the lower end inside the flow tube, it is possible to adjust the distance between the silicon ingot and the adjacent heat shield unit and thereby boost the crystal growth speed and quality, without changing the shape and position of the flow tube.

### BACKGROUND

The present invention relates to the field of semiconductor manufacturing, in particular to a semiconductor crystal growth device.

The Czochralski method (Cz) is an important method of preparing single-crystal silicon for use in semiconductors and photovoltaic (PV) industry. The high-purity silicon material placed in the crucible is heated by a hot zone composed of carbon materials and is melted, and then a single-crystal ingot is finally Obtained by immersing seed crystal in the melt and subjecting to a series of (Neck, Shoulder, Body, Tail, Cooling) processes.

During the crystal pulling process, a heat shield unit, such as a flow tube or a reflective shield, is often disposed around the produced silicon ingot. On the one hand, it is used to isolate the heat radiation generated on the crystal surface by quartz crucible and the silicon melt in the crucible during the crystal growth process, increase the axial temperature gradient of the ingot, make the radial temperature distribution balanced as much as possible, and control the growth rate of the ingot within an appropriate range while controlling the internal defects of the crystal. On the other hand, it is used to guide inert gas introduced from the upper part of the crystal growth furnace to pass through the free surface of the silicon melt at a relatively large flow rate to achieve the effect of controlling oxygen content and impurity content in the silicon ingot crystal.

In the design process of the semiconductor crystal growth device, it is often necessary to consider the distance between the heat shield unit and silicon melt free surface and the distance between the heat shield unit and the ingot to control the axial temperature gradient and radial temperature distribution of the ingot. Specifically, during the design process, it often needs to consider two important parameters, i.e., the minimum distance between the heat shield unit and silicon melt free surface (hereinafter referred to as the melt surface distance denoted by Drm) and the minimum distance between the heat shield unit and the ingot (hereinafter referred to as the crystal distance denoted by Drc). Wherein, Drm controls the stable growth of silicon crystals between the crystal pulling liquid levels, and Drc controls the temperature gradient of the silicon crystal in the axial direction. In order to achieve the stable growth of silicon crystals between the silicon ingot and the silicon melt liquid surface, the lifting velocity of the crucible is often controlled to keep the Drm within a suitable range. For example, the Japanese Patent Application No. JP2000160405 discloses a growth method and device for semiconductor crystals. A heat shielding device is disposed around the single-crystal silicon, and controls the formation of defective crystal regions in the single-crystal silicon when the single-crystal silicon is pulled out by defining the distance from the bottom surface of the heat shielding device to the surface of the silicon melt and the pulling speed when the single-crystal silicon is pulled out. However, when the heat shield unit is settled, the shape and position of the flow tube are fixed. With the constant diameter of the silicon crystal, it is difficult to further reduce the Dre to achieve a large axial temperature gradient of the silicon crystal by controlling the heat shield unit itself.

To this end, it is necessary to propose a new semiconductor growth device to solve the problems in the prior art.

### SUMMARY

A series of simplified forms of concepts is introduced into the portion of Summary, which would be further illustrated in the portion of the detailed description. The Summary of the present invention does not mean attempting to define the key features and essential technical features of the claimed technical solution, let alone attempting to determine the protection scope thereof.

The present invention provides a semiconductor crystal growth device, comprising:

a furnace body;

a crucible disposed inside the furnace body for containing a silicon melt;

a pulling unit disposed at a top portion of the furnace body for pulling out a silicon ingot from the silicon melt; and

a heat shield unit including a flow tube that is barrel-shaped and disposed around the silicon ingot for rectifying argon gas input from the top portion of the furnace body and adjusting thermal field distribution between the silicon ingot and the silicon melt liquid surface, wherein, the heat shield unit further includes an adjustment unit disposed at a lower end inside the flow tube for adjusting a minimum distance between the heat shield unit and the silicon ingot.

Exemplarily, the adjustment unit includes an annular device disposed surrounding an inner side of the flow tube.

Exemplarily, the annular device is spliced by at least two arc-shaped parts.

Exemplarily, the adjustment unit is detachably connected to the flow tube.

Exemplarily, the flow tube includes an inner cylinder, an outer cylinder, and a heat insulating material, wherein bottom of the outer cylinder extends below the bottom of the inner cylinder and is closed with the bottom of the inner cylinder so as to form a cavity between the inner cylinder and the outer cylinder, and the heat insulating material is provided in the cavity.

Exemplarily, the adjustment unit includes an inserting portion and a protruding portion, the inserting portion being inserted into a position between a portion of the bottom of the outer cylinder that extends to below the bottom of the inner cylinder and the bottom of the inner cylinder.

Exemplarily, the cross section of the adjustment unit is in an inverted L shape or a T shape rotated 90° counterclockwise.

Exemplarily, the protruding portion is configured in an inverted triangle shape or in a shape protruding to the silicon ingot.

Exemplarily, the protruding portion extends downward beyond the bottom of the flow tube.

Exemplarily, the shape of the protruding portion extending downward beyond the bottom of the flow tube includes an inner concave curved surface or an outer convex curved surface.

Exemplarily, the material of the adjustment unit includes a material of low thermal conductivity coefficient.

Exemplarily, the material of the adjustment unit includes single-crystal silicon, graphite, quartz, high melting point metal or a combination of the foregoing materials.

Exemplarily, a low thermal radiation coefficient layer is provided on a side of the protruding portion facing the silicon ingot to further change radiative heat transfer between the adjustment unit and the surface of the silicon ingot.

According to the semiconductor crystal growth device of the present invention, in the design of the heat shield unit, by providing the adjustment unit at a lower end inside the flow tube, it is possible to reduce the minimum distance between the heat shield unit and the ingot and increase axial temperature gradient of the silicon ingot, thereby boosting the crystal growth speed, without changing the shape and position of the flow tribe. At the same time, the difference value of the axial temperature gradient between the center and the edge of the ingot is reduced, which is conducive to the stable growth of the crystal. Meanwhile, by reducing the minimum distance Drc between the heat shield unit and the ingot, the adjustment unit can change the gas flow rate of the gas flowing to the silicon melt liquid surface through the flow tube and that spreading from the silicon melt liquid surface in the radial direction, adjust the oxygen content of the crystal, and further improve the crystal pulling quality.

### BRIEF DESCRIPTION OF THE DRAWINGS

The following drawings are hereby incorporated as part of the present invention for the understanding of the present invention. The drawings illustrate embodiments of the present invention and description thereof for explaining the principle of the present invention.

In the drawings:

FIG. 1 is a structural schematic diagram of a semiconductor crystal growth device according to an embodiment of the present invention;

FIG. 2 is a structural schematic diagram of an adjustment unit installed on a flow tube according to an embodiment of the present invention;

FIGS. 3A-3C are respectively structural schematic diagrams of an adjustment unit according to an embodiment of the present invention.

### DETAILED DESCRIPTION

In the following description, numerous specific details are set forth in order to provide a more thorough understanding of the present invention. However, it is obvious to those skilled in this art that the present invention may be implemented without one or more of these details. Some technical features well-known in this art are not described in other examples in order to avoid confusion with the present invention.

In order to thoroughly understand the present invention, a detailed description will be provided in the following description to illustrate the semiconductor crystal growth device of the present invention. Obviously, the implementation of the present invention is not limited to the specific details familiar to those skilled in the semiconductor field. The preferred embodiments of the present invention are described in detail as follows. However, in addition to these detailed descriptions, the present invention may have other embodiments.

It shall be noted that the terminology used herein is for the purpose of describing particular embodiments only and is not intended to limit the exemplary embodiments of the present invention. As used herein, the singular forms are intended to include the plural forms as well, unless the context clearly indicates otherwise. It will be further understood that the terms “comprising” and/or “including,” when used in this specification, specify the presence of stated features, wholes, steps, operations, elements, and/or components, but do not preclude the presence or addition of one or more other features, wholes, steps, operations, elements, components, and/or combinations thereof.

Now, exemplary embodiments according to the present invention will be described in more detail with reference to the accompanying drawings. However, these exemplary embodiments can be implemented in many different forms, and should not be construed as being limited to the embodiments set forth herein. It should be understood that these embodiments are provided to make the disclosure of the present invention thorough and complete, and to fully convey the concept of these exemplary embodiments to those of ordinary skill in the art. In the drawings, the thicknesses of layers and regions are exaggerated for clarity, and the same reference numerals are used to denote the same elements, whose descriptions will thus be omitted.

In order to solve the technical problems in the prior art, the present invention provides a semiconductor crystal growth device, comprising:

a furnace body;

a crucible disposed inside the furnace body for containing a silicon melt;

a pulling unit disposed at a top portion of the furnace body for pulling out a silicon ingot from the silicon melt; and

a heat shield unit including a flow tube that is barrel-shaped and disposed around the silicon ingot for rectifying argon gas input from the top portion of the furnace body and adjusting thermal field distribution between the silicon ingot and the silicon melt liquid surface, wherein, the heat shield unit further includes an adjustment unit disposed at a lower end inside the flow tube for adjusting a minimum distance between the heat shield unit and the silicon ingot.

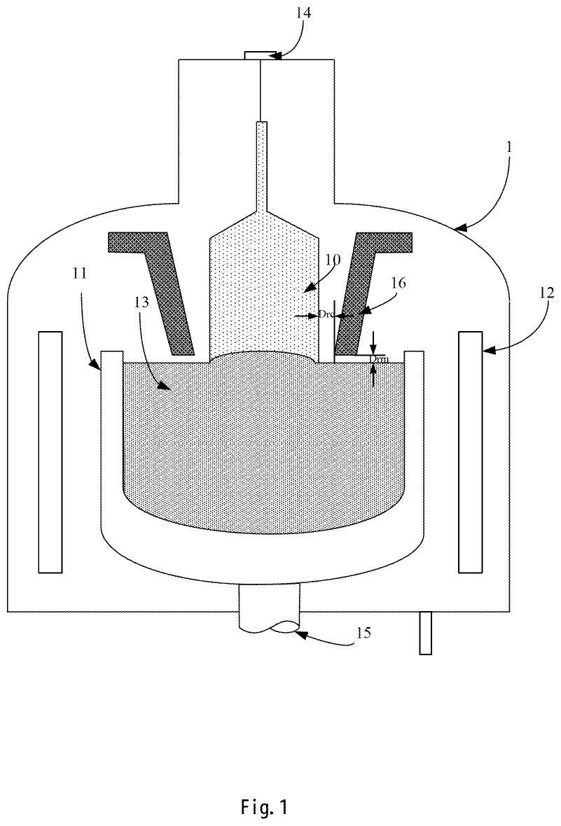

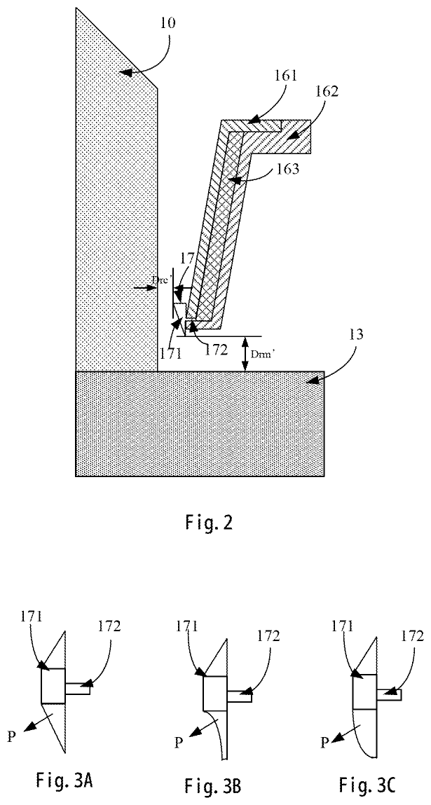

The following is an exemplary description of a semiconductor crystal growth device proposed by the present invention with reference to FIGS. 1 and 2. FIG. 1 is a structural schematic diagram of a semiconductor crystal growth device according to an embodiment of the present invention, FIG. 2 is a structural schematic diagram of an adjustment unit installed on a flow tube according to an embodiment of the present invention, FIG. 3A to FIG. 3C are respectively structural schematic diagrams of an adjustment unit according to an embodiment of the present invention.

The Czochralski method (Cz) is an important method of preparing single-crystal silicon for use in semiconductors and PV industry. The high-purity silicon material placed in the crucible is heated by a hot zone composed of carbon materials and is melted, and then a single-crystal ingot is finally obtained by immersing seed crystal in the melt and subjecting to a series of (Neck, Shoulder, Body, Tail, Cooling) processes.

Referring to FIG. 1, it shows a semiconductor crystal growth device according to an embodiment of the present invention. The semiconductor crystal growth device includes a furnace body 1 in which a crucible 11 is provided. A heater 12 for heating the crucible 11 is provided outside the crucible 11. A silicon melt 13 is contained in the crucible 11.

A pulling unit 14 is provided at a top portion of the furnace body 1. Under the driving of the pulling unit 14, the seed crystal pulls out the silicon ingot 10 from the silicon melt liquid surface. At the same time, a heat shield unit is disposed around the silicon ingot 10. Exemplarily, as shown in FIG. 1, the heat shield unit includes a flow tube 16, which is configured in a conical barrel shape and serves as a heat shield unit, on the one hand, to isolate the heat radiation generated by the quartz crucible and the silicon melt in the crucible to the crystal surface during the crystal growth process, boost the cooling rate and axial temperature gradient of the ingot, and increase the number of crystal growth. On the other hand, it affects the thermal field distribution of the silicon melt surface and thereby avoids the axial temperature gradient between the center and edge of the ingot from differentiating too largely so as to ensure the stable growth between the ingot and the silicon melt liquid surface. Meanwhile, the flow tube is also used to guide the inert gas introduced from the upper part of the crystal growth furnace to cause it to pass through the silicon melt surface at a relatively large flow rate to achieve the effect of controlling oxygen content and impurity content in the crystal. Continuing with reference to FIG. 1, the minimum distance between the bottom of the flow tube 16 and the liquid surface of the silicon melt 13 is used as the minimum distance between the heat shield unit and the silicon melt, which is called the liquid surface distance and denoted by Drm. The minimum distance from the silicon ingot to the position of the flow tube 16 that is closest to the silicon ingot 10 is used as the minimum distance between the heat shield unit and the silicon ingot, which is called the ingot distance and denoted by Drc.

In order to realize stable growth of the silicon ingot, a driving device 15 for driving the crucible 11 to rotate and move up and down is also provided at the bottom of the furnace body 1. The driving device 15 drives the crucible 11 to keep rotating during the crystal pulling process to reduce the asymmetry of heat of the silicon melt and make the silicon ingot grow with equal diameter. The driving device 15 drives the crucible to move up and down to control the liquid surface distance Drm within a reasonable range and maintain the stability of thermal radiation of the silicon melt liquid surface, thereby meeting the requirements of stable growth of the silicon ingot. Exemplarily, the driving device 15 drives the crucible to move up and down to control the liquid surface distance Drm between 20 mm and 80 mm.

However, when the heat shield unit is settled, the shape and position of the flow tube are fixed. With the constant shape of the silicon ingot, it is difficult to further reduce Drc to achieve a large axial temperature gradient of the silicon ingot by controlling the device itself.

To this end, referring to FIG. 2, in the semiconductor crystal growth device of the present invention, an adjustment unit 17 is provided at a lower end of the flow tube 16, so that the adjustment unit 17 along with the flow tube 16 serve as a heat Shield unit for adjusting the hot zone distribution between the silicon melt liquid surface and the ingot. Specifically, the adjustment unit is provided, at the lower end inside the flow tube, Without adjusting the size and position of the flow tube, the minimum distance Drc between the heat Shield unit and the silicon ingot is changed from the minimum distance between the initial flow tube and the ingot to the minimum distance between the adjustment unit and the ingot compared with the case where the adjustment unit is not installed, so that the minimum distance are between the heat shield unit and the ingot is reduced, and the heat shield unit readjusts the radiation energy between the silicon ingot and the heat shield unit and that between the heat shield unit and the silicon melt liquid surface. Accordingly, the heat flux intensity and distribution of the crystal surface are adjusted to increase the axial temperature gradient between the center and edge of the silicon ingot, which effectively boosts the crystal growth speed. At the same time, the difference value of the axial temperature gradient between the center and the edge is reduced, which is conducive to the stable growth of the crystal on the silicon melt liquid surface. Meanwhile, the adjustment unit also reduces the size of the channel through which argon gas flows to the silicon melt liquid surface through the flow tube, thereby adjusting gas flow rate of the argon gas spreading from the silicon melt liquid surface in the radial direction, adjusting the oxygen content of the grown crystals, and further improving the crystal pulling quality.

Furthermore, when the adjustment unit is provided, the minimum distance Drc between the heat shield unit and the silicon ingot is reduced such that the radiative heat transfer from the silicon melt liquid surface to the ingot is decreased, and the axial temperature gradient of the ingot is increased, which is beneficial to boost the growth rate of crystals while reduce the power consumption of the heater for crystal growth. The adjustment unit provided between the flow tube and the ingot can also reduce the radiative heat transfer from the flow tube to the ingot, thereby decreasing the difference value of the axial temperature gradient between the center and the edge of the ingot, such that the process window (pulling speed range) of crystal growth is widened, and the yield of the product is improved.

The flow tube is barrel-shaped and is disposed around the silicon ingot. Exemplarily, the adjustment unit 17 is configured as an annular device surrounding an inner side of the flow tube.

Exemplarily, the adjustment unit is detachably connected to the flow tube.

Further, exemplarily, the annular device is spliced by at least two arc-shaped parts. Since the crystal pulling process is in a high-temperature environment, the annular-shaped adjustment unit is configured in a multi-segment arc shape in order to avoid the adjustment unit from inflating in the high-temperature environment to make installation of and fitting with the flow tube unstable, and the configuration of the gap between the multi-segment arcs effectively avoids the problem of unstable fitting between the adjustment unit and the flow tube due to inflation. At the same time, configuring the annular-shaped adjustment unit in the multi-segment arc shape can further simplify the process with which the adjustment unit is installed on the flow tube.

Continuing with reference to FIG. 2, according embodiment of the present invention, the flow tube 16 includes an inner cylinder 161, an outer cylinder 162, and a beat insulating material 163 disposed between the inner cylinder 161 and the outer cylinder 162, wherein the bottom of the outer cylinder 162 extends below the bottom of the inner cylinder 161 and is closed with the bottom of the inner cylinder 161 to form a cavity containing the heat insulating material 163 between the inner cylinder 161 and the outer cylinder 162. Configuring the flow tube as a structure including the inner cylinder, the outer cylinder and the heat insulating material can simplify the installation of the flow tube. Exemplarily, the material of the inner cylinder and the outer cylinder is set to graphite, and the heat insulating material includes glass fiber, asbestos, rock wool, silicate, aerogel felt, vacuum board, and the like.

Continuing with reference to FIG. 2, in the form that the flow tube 16 includes an inner cylinder 161, an outer cylinder 162, and a heat insulating material 163 disposed between the inner cylinder 161 and the outer cylinder 162, the adjustment unit 17 includes a protruding portion 171 and an inserting portion 172 that is configured to be inserted into a position between a portion of the bottom of the outer cylinder 162 that extends to below the bottom of the inner cylinder 161 and the bottom of the inner cylinder 161. The adjustment unit is installed on the flow tube in an inserted form, and the installation of the adjustment unit can be realized without the need to modify the flow tube, which further simplifies the manufacturing of the adjustment unit and the flow tube and reduces installation cost. At the same time, the inserting portion is inserted into a position between the bottom of the outer cylinder and the bottom of the inner cylinder, which effectively reduces the heat transfer from the outer cylinder to the inner cylinder, reduces the temperature of the inner cylinder, further reduces the radiative heat transfer from the inner cylinder to the ingot, effectively reduces the difference value of the axial temperature gradient between the center and the periphery of the silicon ingot, and improves the crystal pulling quality.

Exemplarily, the adjustment unit is configured as a low thermal conductivity coefficient material. Further, the exemplary low thermal conductivity coefficient material includes a material with a thermal conductivity coefficient less than 5-10 W/m*K, Exemplarily, the material of the adjustment unit is set to SIC ceramic, quartz, single-crystal silicon, graphite, carbon fiber high melting point metal, or a combination of the foregoing materials.

It should be understood that the adjustment unit is set to be detachably installed on the flow tube in this embodiment to realize their installation and separate manufacture, simplify the manufacturing process, and reduce the manufacturing cost on the one hand. On the other hand, the adjustment unit can also be replaced individually, and processed and used as a consumable component, such that it can be formed into a series of products to shorten the research and development cycle and reduce the development cost. Those skilled in the art should understand that configuring the adjustment unit to be integrally manufactured with the inner cylinder of the flow tube is also suitable for the present invention.

Exemplarily, the cross section of the adjustment unit is in an inverted L shape or a T shape rotated 90° counterclockwise. Continuing with reference to FIG. 2, the cross section of the adjustment unit 17 is a T-shape rotated 90° counterclockwise, in which the inserting portion 172 is inserted into a position between a portion of the bottom of the outer cylinder 162 that extends to below the bottom of the inner cylinder 161 and the bottom of the inner cylinder 161. The protruding portion 171 is configured as an inverted triangle to reduce the minimum distance between the ingot and the heat shield unit.

It should be understood that it is only exemplary that the protruding portion is configured as an inverted triangle, and it can also be configured in any shape protruding to the silicon ingot. Any shape that can reduce the minimum distance between the ingot and the heat shield unit is applicable to the present invention.

Referring to FIGS. 3A to 3C, it is shown that the protruding portion 171 is configured in a shape protruding to the ingot. As shown in FIGS. 3A-3C, the protruding portion 171 extends downward beyond the bottom of the flow tube, as shown by the arrow P in the figure. As shown in FIG. 2, the protruding portion extends downward out of the bottom of the flow tube. Without changing the size and position of the flow tube, the minimum distance Dun between the heat shield unit and the silicon melt liquid surface is changed from the minimum distance between the bottom of the flow tube and the silicon melt liquid surface to the minimum distance between the lower end of the protruding portion of the adjustment unit and the liquid surface of the silicon cylinder, so that the minimum distance Drm between the heat shield unit and the silicon melt liquid surface is reduced to change the gas flow rate of the gas flowing to the silicon melt liquid surface through the flow tube and that spreading from the silicon melt liquid surface in the radial direction, control the oxygen concentration inside the silicon melt near the periphery of the silicon crystal, adjust the oxygen content of the crystal, and further improve the crystal pulling quality.

Exemplarily, the shape of the protruding portion 171 extending downward beyond the bottom of the flow tube includes an inner concave curved surface (as shown in FIG. 3B) or an outer convex curved surface (as shown in FIG. 3C). The shape of the protruding portion extending downward beyond the bottom of the flow tube is configured as an inner concave curved surface or an outer convex curved surface. The relative shape between the adjustment unit and the silicon melt liquid surface can further adjust the radiative heat transfer between the silicon ingot surface, the silicon melt liquid surface and the adjustment unit, as well as the direction of the crystal surface along the axial direction. The change in the heat flux released from the crystal to outside reduces the difference value of the axial temperature gradient between the center and the edge so as to achieve a more flat interface between the crystal and the melt and reduce the effect of the radial difference of the crystal.

Exemplarily, a side of the protruding portion facing the silicon ingot is provided with a low thermal radiation coefficient (high reflection coefficient) layer to further reduce the radiative heat transfer between the flow tube and the silicon ingot surface. The thermal radiation coefficient e is between 0-1 (reflection coefficient p=1−e) Exemplarily, the thermal radiation coefficient e of the low radiation coefficient material is less than 0.5. In one example, the protruding portion is made of polished stainless steel, wherein the polished stainless steel surface has a thermal radiation coefficient e=0.2-0.3.

Exemplarily, the material of the adjustment unit is set to graphite. The surface of the graphite is subject to surface treatment to form a SiC coating and/or a thermally decomposed carbon coating, and the thickness of the coating is between 10 μm and 100 μm. The surface of the thermally decomposed carbon coating has high compactness and high heat reflection coefficient at high temperature. The surface treatment methods include chemical vapor deposition, and the like.

Exemplarily, the coating treatment is applied to the shape and surface of the protruding portion of the adjustment unit to form a high reflection coefficient (low thermal radiation coefficient) layer on the surface, change the radiative heat transfer between the surface of the silicon ingot and liquid surface and the adjustment unit, and adjust the direction of the crystal surface along the axial direction. The change in the heat flux released from the crystal to outside reduces the difference value of the axial temperature gradient between the center and the edge so as to achieve a more flat interface between the crystal and the melt and reduce the effect of the radial difference of the crystal.

The semiconductor crystal growth device according to the present invention has been exemplarily introduced above. It should be understood that the limitation on the shape, mounting method, and material of the adjustment unit in the semiconductor crystal growth device in this embodiment is only exemplary. Any adjustment unit that can reduce the minimum distance between the ingot and the heat shield unit is applicable to the present invention.

In summary, according to the semiconductor crystal growth device of the present invention, by providing the adjustment unit at the lower end inside the flow tube, itis possible to reduce the minimum distance between the heat shield unit and the ingot and increase axial temperature gradient of the silicon ingot, thereby boosting the crystal growth speed, without changing the shape and position of the flow tube. At the same time, the difference value of the axial temperature gradient between the center and the edge is reduced, which is conducive to the stable growth of the crystal. Meanwhile, by reducing the minimum distance between the heat shield unit and the ingot, the adjustment unit reduces the size of the channel through which the argon gas flows to the silicon melt liquid surface through the flow tube, Which can change the gas flow rate of the gas flowing to the silicon melt liquid surface through the flow tube and that spreading from the silicon melt liquid surface in the radial direction, control the oxygen concentration inside the silicon melt near the periphery of the silicon crystal, adjust the oxygen content of the crystal, and further improve the crystal pulling quality.

The present invention has been described by the above embodiments, but it is to be understood that the embodiments are for the purpose of illustration and explanation only, and are not intended to limit the present invention within the scope of the embodiments described herein. Furthermore, those skilled in the art can understand that the present invention is not limited to the above embodiments. Various variations and modifications can be made according to the teachings of the present invention. These variations and modifications may fall within the protection scope of the present invention as defined in the appended claims and their equivalents.

What is claimed is:

1. A semiconductor crystal growth device, wherein it comprises:
a furnace body;
a crucible disposed inside the furnace body for containing a silicon melt;
a pulling unit disposed at a top portion of the furnace body for pulling out a silicon ingot from the silicon melt; and
a heat shield unit including a flow tube that is barrel-shaped and disposed around the silicon ingot for rectifying argon gas input from the top portion of the furnace body and adjusting thermal field distribution between the silicon ingot and the silicon melt liquid surface, wherein, the heat shield unit further includes an adjustment unit disposed at a lower end inside the flow tube for adjusting a minimum distance between the heat shield unit and the silicon ingot.

2. The semiconductor crystal growth device according to claim 1, wherein the adjustment unit includes an annular device disposed surrounding an inner side of the flow tube.

3. The semiconductor crystal growth device according to claim 2, wherein the annular device is spliced by at least two arc-shaped parts.

4. The semiconductor crystal growth device according to claim 1, wherein the adjustment unit is detachably connected to the flow tube.

5. The semiconductor crystal growth device according to claim 1, wherein the flow tube includes an inner cylinder, an outer cylinder, and a heat insulating material, wherein bottom of the outer cylinder extends below the bottom of the inner cylinder and is closed with the bottom of the inner cylinder so as to form a cavity between the inner cylinder and the outer cylinder, and the heat insulating material is provided in the cavity.

6. The semiconductor crystal growth device according to claim 5, wherein the adjustment unit includes an inserting portion and a protruding portion, the inserting portion being inserted into a position between a portion of the bottom of the outer cylinder that extends to below the bottom of the inner cylinder and the bottom of the inner cylinder.

7. The semiconductor crystal growth device according to claim 6, wherein the cross section of the adjustment unit is in an inverted L shape or a T shape rotated 90° counterclockwise.

8. The semiconductor crystal growth device according to claim 6, wherein the protruding portion is configured in an inverted triangle shape or in a shape protruding to the silicon ingot.

9. The semiconductor crystal growth device according to claim 8, wherein the protruding portion extends downward beyond the bottom of the flow tube.

10. The semiconductor crystal growth device according to claim 8, wherein the shape of the protruding portion extending downward beyond the bottom of the flow tube includes an inner concave curved surface or an outer convex curved surface.

11. The semiconductor crystal growth device according to claim 1, wherein the material of the adjustment unit includes a material of low thermal conductivity coefficient.

12. The semiconductor crystal growth device according to claim 10, wherein the material of the adjustment unit includes single-crystal silicon, graphite, quartz, high melting point metal or a combination of the foregoing materials.

13. The semiconductor crystal growth device according to claim 9, wherein a low thermal radiation coefficient layer is provided on a side of the protruding portion facing the silicon ingot to further change radiative heat transfer between the adjustment unit and the silicon ingot surface.
